(19) United States
(12) Patent Application Publication
(10) Pub. No.: US 2026/0182422 A1
(43) Pub. Date: Jun. 25, 2026

(54) ELECTRONIC DEVICE COMPRISING A SINGLE DIELECTRIC LAYER FOR SOLDER MASK AND CAVITY AND METHOD FOR FABRICATING THE SAME

(71) Applicant: Qorvo US, Inc., Greensboro, NC (US)

(72) Inventors: John August Orlowski, Summerfield, NC (US); Thomas Scott Morris, Lewisville, NC (US)

(21) Appl. No.: 19/534,061

(22) Filed: Feb. 9, 2026

Related U.S. Application Data
(62) Division of application No. 18/273,464.
(60) Provisional application No. 63/146,080, filed on Feb. 5, 2021.

(51) Int. Cl. H10W 70/65; H10W 70/05; H10W 70/69

(52) U.S. Cl. CPC H10W 70/65; H10W 70/05; H10W 70/69

(57) ABSTRACT

Systems and methods of the present disclosure are directed to an electronic substrate. The electronic substrate includes a base layer, first feature(s) formed from a first metal layer and a second metal layer, and second feature(s) formed from the first metal layer. The electronic substrate includes a polymerized photodielectric layer over the first feature(s) and the second feature(s). The polymerized photodielectric layer exposes a portion of the second metal layer of the first feature(s), and at least a portion of the first metal layer of the second feature(s).

### RELATED APPLICATIONS

This application is a divisional of U.S. patent application Ser. No. 18/273,464, filed Jul. 20, 2023, which is a 35 USC 371 national phase filing of International Application No. PCT/US2022/015419, filed Feb. 7, 2022, which claims the benefit of provisional patent application Ser. No. 63/146,080, filed Feb. 5, 2021, the disclosures of which are incorporated herein by reference in their entireties.

### FIELD OF THE DISCLOSURE

The present disclosure relates to electronic substrates with a single dielectric layer for both solder mask and cavity.

### BACKGROUND

Electronic substrates are often used to support and connect electrical components and electronic modules. Laminate structures, including printed circuit boards (PCBs) and the like, are commonly used as electronic substrates for electronic devices. A typical laminate structure may include a non-conductive body for support and one or more conductive features for connecting semiconductor die, electrical components, and electronic modules. Some of the conductive features can be exposed at a surface of the non-conductive body and may include contact pads, conductive traces, surface-exposed sections of vias, and the like. Electrical components are mounted to the exposed conductive features to form electronic devices, modules, and circuits.

PCBs are electronic substrates that are often used to mount electrical components housed within integrated circuit (IC) packages. For example, a semiconductor die is often mounted on a PCB and then covered with an overmold in order to protect the semiconductor die. Traditional PCBs are often formed from a laminate structure of non-conductive and conductive layers. The conductive layers can form a conductive structure of the PCB that is arranged to connect input and output structures of the semiconductor die to other electrical components within the IC package and/or to input and output structures of the IC package accessible externally from the IC package. The conductive structure typically has conductive layers formed horizontally between the non-conductive layers and/or on a substrate surface. These conductive layers are shaped to form various structures, such as traces, terminals, contact pads, and the like to connect electrical components within the IC package and/or the input and output structures of the IC package to the electrical components.

In conventional approaches to electronic substrate fabrication, such as PCBs, metal layer 1 (M1) and metal layer 2 (M2) processing is completed to form features on the electronic substrate, with a dielectric layer positioned between M1 and M2, and a via connecting the M1 and M2 layers. FIG. 1 is a diagram that illustrates conventional completion of M1 processing for an electronic substrate. As illustrated, M1 and M2 processing is completed such that a bottom surface of the M2 layer contacts a top layer of the base layer, the top surface of the M2 layer contacts the bottom surface of the dielectric layer, and the bottom surface of the M1 layer contacts the top surface of the dielectric layer. To form a capture pad, a connection is formed through the dielectric layer with a via from a portion of the M2 layer to a portion of the M1 layer. Finally, the dielectric layer is thermally cured. It should be noted that conventionally, because the cured dielectric layer cannot be reduced with photolithography, the usage of a via is necessary to form features such as the capture pads.

After curing the dielectric layer, a portion of the dielectric layer is removed (e.g., via laser ablation, etc.) to form a cavity to the M2 layer. FIG. 2 illustrates a diagram showing removal of the dielectric layer (e.g., by laser ablation, etc.) to form the cavity down to the M2 layer and the corresponding features (e.g., traces). It should be noted that utilizing laser ablation to form the cavity, while necessary in conventional techniques, is generally considered to be a relatively slow and expensive aspect of electronic substrate formation.

As illustrated in FIG. 3, a laminate solder resist is then applied over the M1 layer, the dielectric layer, and portions of the M2 layer and base layer (e.g., those portions exposed in the cavity). As illustrated in FIG. 4, the solder resist is exposed to selectively polymerize certain portions of the solder resist. For example, the solder resist may be a conventional photolithographic resist material that is exposed to light.

After selective polymerization, the solder resist is developed to remove any portion of the solder resist that was not selectively polymerized. FIG. 5 illustrates the development of remaining unexposed solder resist to expose features of the electronic substrate. For example, by developing the remaining unexposed solder resist, the contact pads and traces formed by the M1 and M2 layers are exposed along with the cavity previously created via laser ablation.

The art continues to seek improved electronic devices and related fabrication techniques capable of overcoming challenges associated with conventional electronic devices.

### SUMMARY

In one aspect, an electronic substrate comprises a base layer, one or more first features, and one or more second features. The first features are formed from a first metal layer and a second metal layer. A bottom surface of the first metal layer contacts a top surface of the base layer, and a bottom surface of the second metal layer contacts a top surface of the first metal layer or a top surface of a layer between the first metal layer and the second metal layer. The one or more second features are formed from the first metal layer. The bottom surface of the first metal layer contacts the top surface of the base layer or a top surface of a layer in between the base layer and the first metal layer. The electronic substrate comprises a polymerized photodielectric layer over the one or more first features and the one or more second features. The polymerized photodielectric layer exposes a portion of the second metal layer of the one or more first features, and at least a portion of the first metal layer of the one or more second features.

In certain embodiments, the electronic substrate further comprises one or more third features formed from the first metal layer, wherein a bottom surface of the one or more third features contacts the top surface of the base layer or the top surface of the intermediate layer between the base layer and the first metal layer, and a top surface of the one or more third features contacts a bottom surface of the polymerized photoelectric layer. The polymerized photoelectric layer covers the one or more third features.

In certain embodiments, the polymerized photodieletric layer comprises a film-type photodieletric layer or a liquid-type photodieletric layer.

In certain embodiments, the base layer comprises a non-conductive layer.

In certain embodiments, a width of the second metal layer of the one or more first features is less than a width of the first metal layer of the one or more first features.

In certain embodiments, the polymerized photodielectric layer is thinned to expose the portion of the second metal layer of the one or more first features and the at least the portion of the first metal layer of the one or more second features.

In certain embodiments, the one or more first features comprise one or more respective contact pads, and/or the one or more second features comprise one or more respective traces.

In certain embodiments, the first metal layer and/or the second metal layer comprises copper.

In another aspect, a method for fabricating an electronic substrate with a single dielectric layer for solder mask and cavity is proposed. The method comprises depositing a photodielectric material over one or more first features and one or more second features located on a base layer. The one or more first features are formed from a first metal layer and a second metal layer. A bottom surface of the first metal layer of the one or more first features contacts a top surface of the base layer or a top surface of a layer in between the base layer and the first metal layer. A bottom surface of the second metal layer of the one or more first features contacts a top surface of the first metal layer or a top surface of a layer between the first metal layer and the second metal layer. The one or more second features are formed from the first metal layer. A bottom surface of the first metal layer of the one or more second features contacts a top surface of the base layer. The photodielectric material is deposited over the base layer, the one or more second features, and at least a portion of the second metal layer of the one or more first features. The method comprises selectively polymerizing a first segment of the photodielectric material that covers the at least the portion of the second metal layer of the one or more first features. The method comprises selectively thinning a second segment of the photodielectric material that covers the one or more second features to form a cavity that exposes at least a portion of the one or more second features.

In certain embodiments, selectively thinning the second segment of the photodielectric material comprises selectively thinning the second segment the photodielectric material that covers the one or more second features to form a cavity that exposes a portion of the one or more second features. The method further comprises selectively polymerizing the second segment of the photodielectric material.

In certain embodiments, the photodielectric material is deposited to cover the base layer, the one or more second features, and the second metal layer of the one or more first features such that a top surface of the second metal layer of the one or more first features contacts a bottom surface of the first segment of the photodielectric material. Prior to selectively polymerizing the first segment of the photodielectric material, the method comprises selectively thinning the first segment of the photodielectric material to expose a portion of the second metal layer of the one or more first features.

In certain embodiments, depositing the photodielectric material further comprises depositing the photodielectric material on one or more third features located on the base layer, wherein the one or more third features are formed from the first metal layer, wherein the bottom surface of the first metal layer of the one or more third features contacts the top surface of the base layer or the top surface of a layer in between the base layer and the first metal layer, and the top surface of the first metal layer of the one or more third features contacts a bottom surface of a third segment of the photodielectric material.

In certain embodiments, the method comprises selectively polymerizing the third segment of the photodielectric material.

In certain embodiments, the third segment of the photodielectric material is located between the first and second segments of the photodielectric material.

In certain embodiments, the base layer comprises a non-conductive layer.

In certain embodiments, a width of the second metal layer of the one or more first features is less than a width of the first metal layer of the one or more first features.

In certain embodiments, the one or more first features comprise one or more respective contact pads, and/or the one or more second features comprise one or more respective traces.

In certain embodiments, the first metal layer and/or the second metal layer comprises copper.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a diagram that illustrates conventional completion of M1 processing for an electronic substrate;

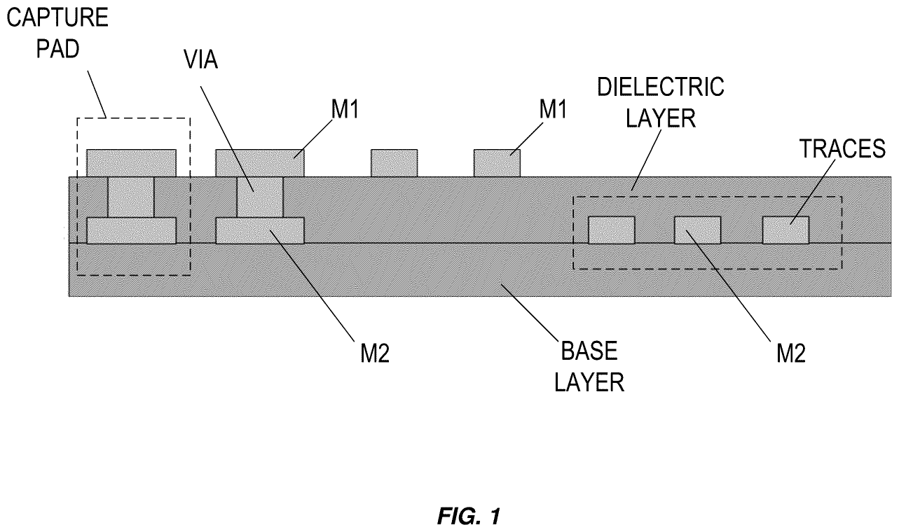

FIG. 2 illustrates a diagram showing removal of the dielectric layer (e.g., by laser ablation, etc.) to form the cavity down to the M2 layer and the corresponding features (e.g., traces) according to known methods;

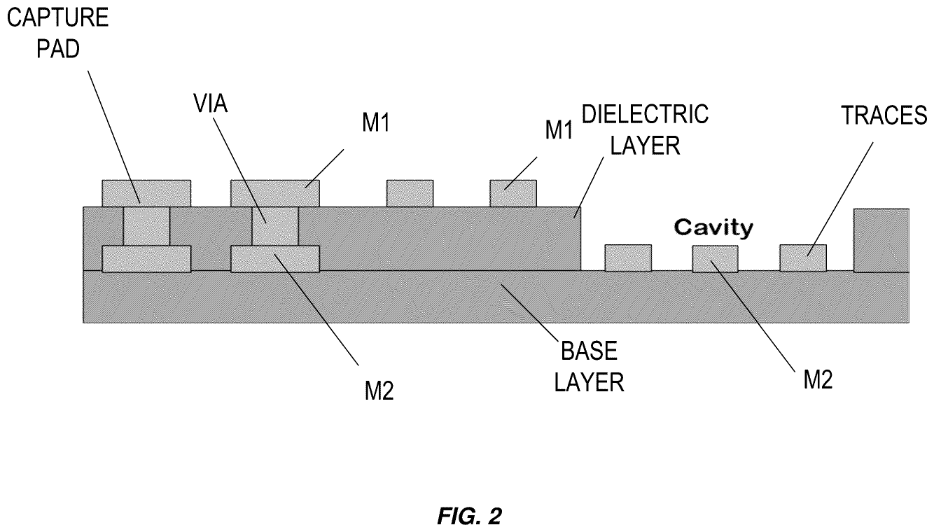

FIG. 3 illustrates a diagram showing a laminate solder resist applied over the M1 layer, the dielectric layer, and portions of the M2 layer and base layer (e.g., those portions exposed in the cavity) according to known methods;

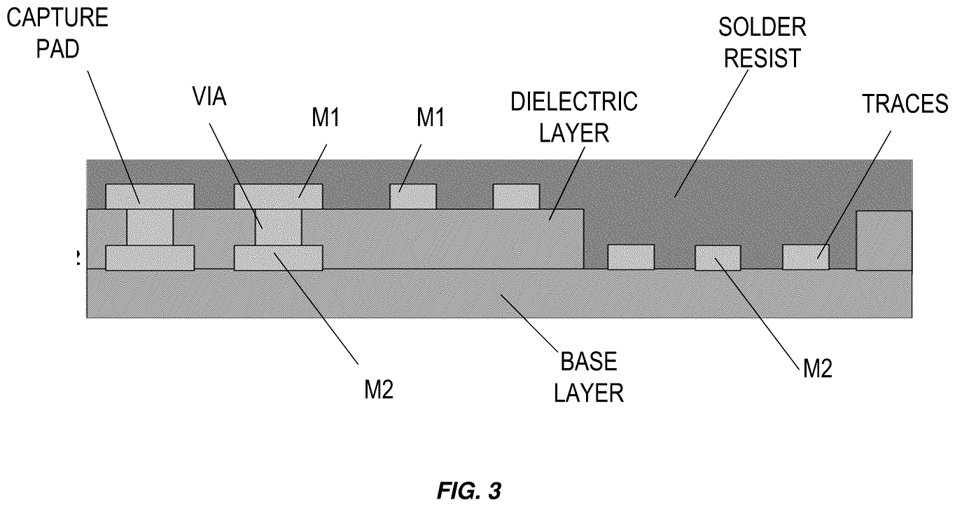

FIG. 4 illustrates a solder resist that is exposed to selectively polymerize certain portions of the solder resist according to known methods;

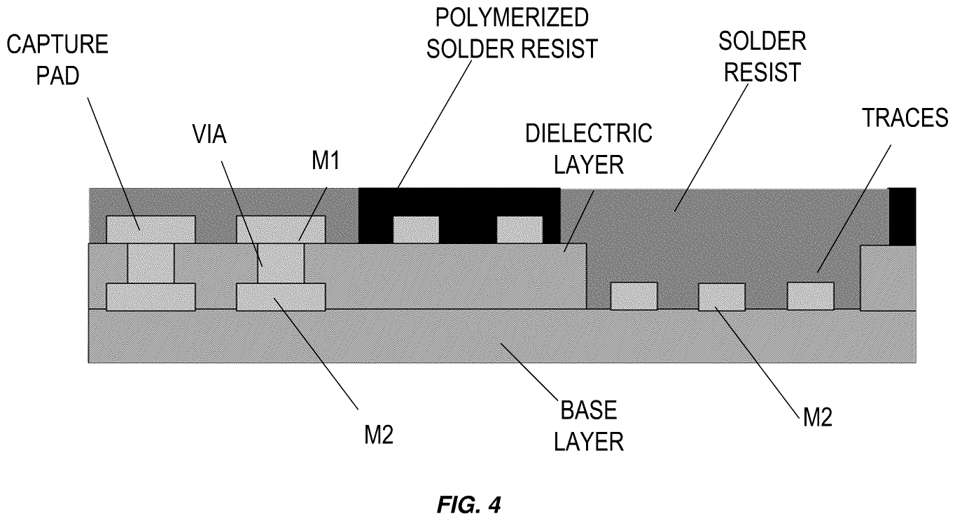

FIG. 5 illustrates the development of remaining unexposed solder resist to expose features of the electronic substrate according to known methods;

FIG. 6 illustrates a diagram for an electronic substrate in which processing of metal layer 1 and metal layer 2 have been completed according to some embodiments of the present disclosure;

FIG. 7 is a diagram that illustrates the electronic substrate after application of a photodielectric layer according to some embodiments of the present disclosure;

FIG. 8 is a diagram that illustrates the electronic substrate of FIG. 7 with a thin photodielectric layer according to some embodiments of the present disclosure;

FIG. 9 is a diagram that illustrates the electronic substrate after selective polymerization of the thin photodielectric layer forms a polymerized photodielectric layer according to some embodiments of the present disclosure;

FIG. 10A is a diagram that illustrates the electronic substrate after thinning of the photodielectric layer to form a completely thinned cavity according to one embodiment of the present disclosure;

FIG. 10B is a diagram that illustrates the electronic substrate after thinning of the photodielectric layer to form a partially thinned cavity according to one embodiment of the present disclosure; and

FIG. 11 is a flowchart for a method for fabricating an electronic substate with a single dielectric layer for solder mask and cavity according to some embodiments of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to electronic substrate processing with a single dielectric layer for solder mask and cavity. Specifically, embodiments of the present disclosure are directed to an electronic substrate, and processes for making electronic substrates, that utilize a photodielectric layer (e.g., a dielectric layer that is reducible via photolithography) for both a dielectric layer and solder mask for cavity formation in the electronic substrates.

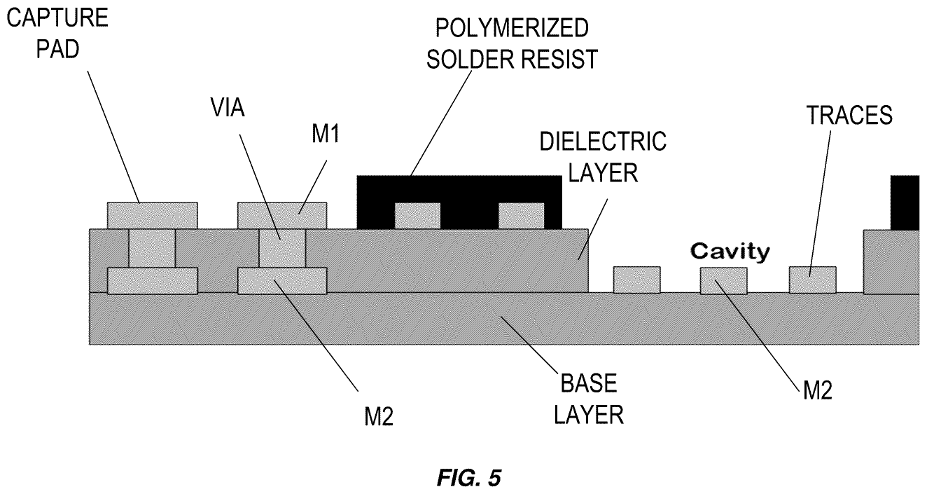

Embodiments of the present disclosure provide a number of technical effects and benefits. As one example, the usage of conventional dielectric layers in electronic substrates, such as the substrate illustrated in FIG. 5, requires the usage of capture pads and vias, which necessarily limits both the quality of features and the minimum thickness of the electronic substrate. Conversely, by using photodielectric materials, embodiments of the present disclosure allow for the formation of high-quality features, and also allow for thinner boards than conventional methods. As another example, conventional techniques such as those illustrated in FIG. 5 must use laser ablation to form cavities in dielectric materials for the electronic substrate. Laser ablation is considered to be a relatively expensive and time-consuming aspect of electronic substrate manufacturing. By utilizing a photodielectric material as both the dielectric layer and the solder mask, embodiments of the present disclosure obviate the need to perform laser ablation, therefore substantially reducing manufacturing time and resource costs.

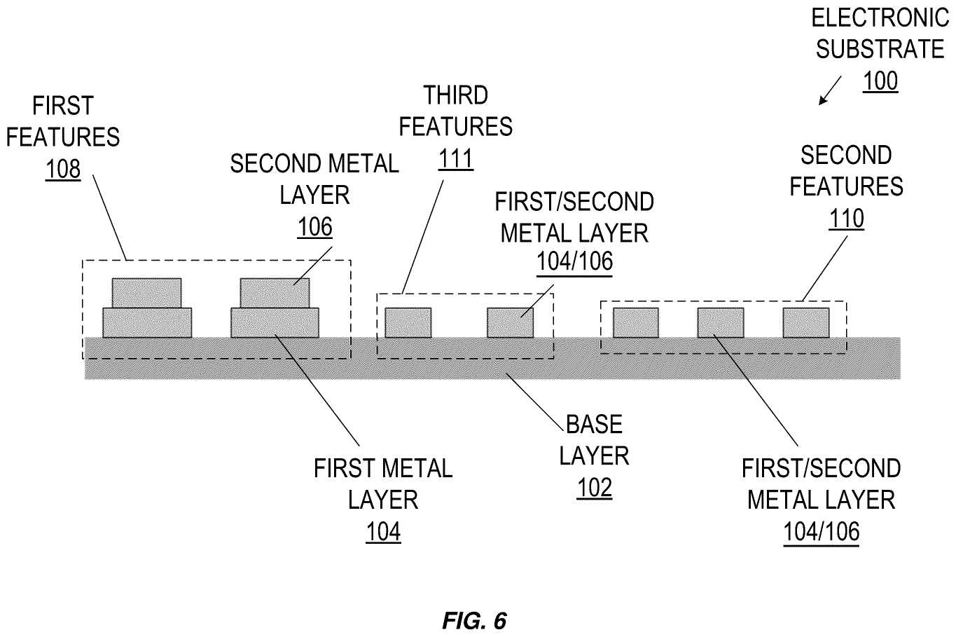

FIG. 6 illustrates a diagram for an electronic substrate 100 in which processing of metal layer 1 and metal layer 2 have been completed according to some embodiments of the present disclosure. Specifically, electronic substrate 100 (e.g., a printed circuit board (PCB), a high density interconnect PCB, etc.) includes a base layer 102 (e.g., a non-conductive layer, etc.), one or more first feature(s) 108 (e.g., one or more contact pads), and one or more second feature(s) 110 (e.g., one or more traces). In some embodiments, the electronic substrate 100 additionally includes one or more third feature(s) 111 (e.g., one or more traces). The features 108, 110, and 111 may be formed from a first metal layer (e.g., M2 layer) 104, a second metal layer (e.g., M1 layer) 106, or either the first or second metal layer 104/106. For example, the first feature(s) 108 may be formed from the first metal layer 104 and the second metal layer 106. In some embodiments, the first and/or second metal layer may be or otherwise include copper.

Specifically, the first feature(s) 108 may be formed such that a bottom surface of the first metal layer 104 of the first feature(s) 108 contacts a top surface of the base layer 102 or of a layer between the base layer and the first features 108, and a bottom surface of the second metal layer 106 contacts a top surface of the first metal layer 104 or a top surface of a layer between the first metal layer and the second metal layer. In such fashion, the metal layers 104 and 106 may be deposited in such a manner to form various features that utilize two or more metal layers. As an example, the first feature(s) 108 may be formed as contact pads on the electronic substrate 100. In some embodiments, a width of the second metal layer 106 in the first features 108 may be less than a width of the first metal layer 104 in the first features 108.

Similarly, the second feature(s) 110 and, in some embodiments, the third feature(s) 111, of the electronic substrate 100 may be formed with either the first metal layer 104 or the second metal layer 106. Specifically, the second and third feature(s) 110 and 111 may be formed either when the first metal layer 104 or the second metal layer 106 is deposited upon the electronic substrate 100. For example, the second feature(s) 110 may be formed from the first metal layer 104 such that the surface of the first metal layer 104 of the second feature(s) 110 contacts the top surface of the base layer 102 or a layer between the base layer 102 and the second feature(s) 110. To follow the previous example, the third feature(s) 111 may be formed subsequently by the first metal layer 104 such that the bottom surface of the first metal layer 104 of the third feature(s) 111 contacts the top surface of the base layer 102 or a layer between the base layer 102 and the third feature(s) 111. In such fashion, the first metal layer 104 may be deposited to form features that only require one metal layer. For example, the second feature(s) 110 and/or third feature(s) 111 may be formed as traces on the electronic substrate 100.

It should be noted that the first and second metal layers 104 and 106 may be deposited using techniques that enable the formation of features that do not require a via connect, such as first feature 108. Specifically, U.S. Pat. No. 10,905,007, “Contact Pads for Electronic Substrates and Related Methods”, describes systems and methods for formation of features such as first features 108 of the electronic substrate 100. However, any other technique that enables such feature formation may be used.

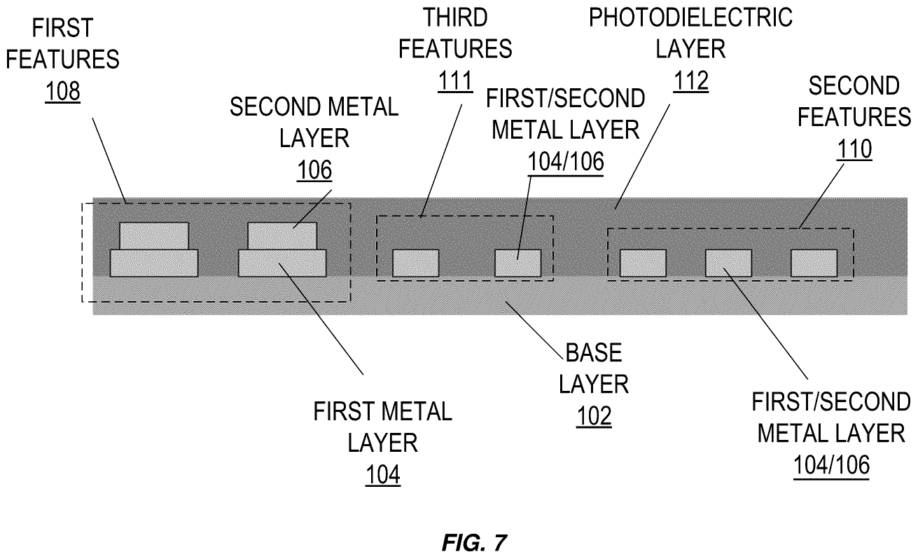

FIG. 7 is a diagram that illustrates the electronic substrate 100 after application of a photodielectric layer 112 according to some embodiments of the present disclosure. Specifically, the photodielectric layer 112 may be applied over the base layer 102, the one or more first features 108, the one or more second features 110, and in some embodiments, the one or more third features 111. The photodielectric layer 112 is a layer formed from a material that is a dielectric and is also a resist that can be reduced via exposure. It should be noted that the photodielectric layer may be or otherwise include any conventional photodielectric material (e.g., a film-type photodielectric such as Taiyo© SR1 Solder Mask, a liquid-type photodielectric such as Taiyo© AUS308 Solder Mask, etc.)

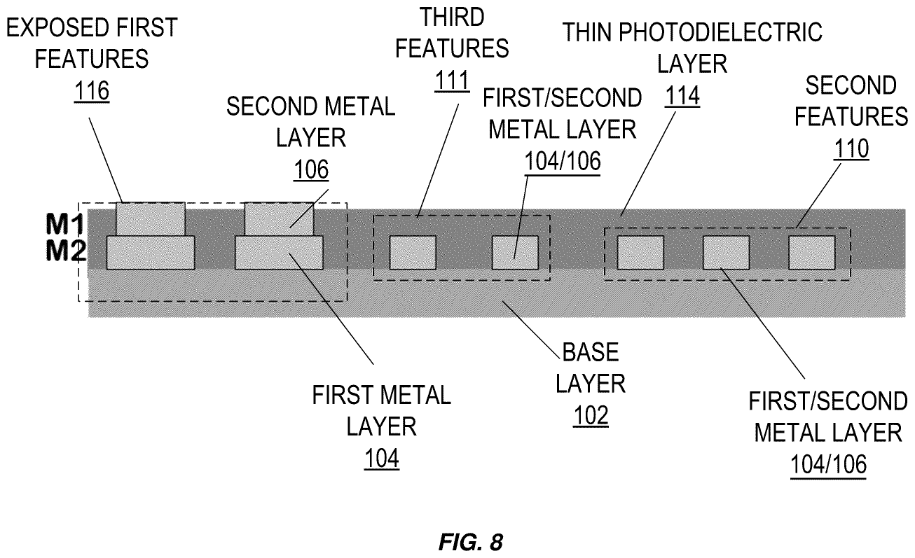

FIG. 8 is a diagram that illustrates the electronic substrate 100 of FIG. 7 with a thin photodielectric layer 114 according to some embodiments of the present disclosure. Specifically, in some embodiments, the thin photodielectric layer 114 may be formed by thinning the photodielectric layer 112 of FIG. 7. For example, the photodielectric layer 112 may be thinned using a grind process, an etch process, or any other technique to reduce the photodielectric layer 112. Alternatively, in some embodiments, the thin photodielectric layer 114 is formed by applying less of the photodielectric material to the electronic substrate 100 of FIG. 6. In other words, less of the photodielectric material can be applied to form the thin photodielectric layer 114 so that a thinning process is not required.

By thinning the photodielectric layer, or applying a thinner layer of the photodielectric material, the thin photodielectric layer 114 exposes the first features 108 of FIGS. 6 and 7 to form exposed first features 116. Specifically, exposure of this portion of the features enables the exposed first features 116 to act as contact pads, or other similar features.

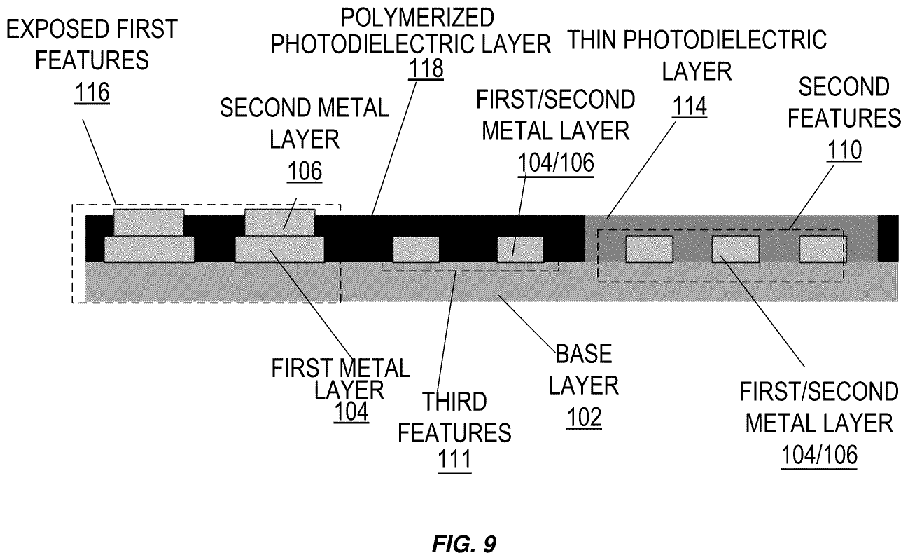

FIG. 9 is a diagram that illustrates the electronic substrate 100 after selective polymerization of the thin photodielectric layer 114 forms a polymerized photodielectric layer 118 according to some embodiments of the present disclosure. It should be noted that only a portion of the thin photodielectric layer 114 has been polymerized to form the polymerized photodielectric layer 118. Specifically, the portion of the thin photodielectric layer 114 that exposes portions of the exposed first features 116 is polymerized, and in some embodiments, the portion of the thin photodielectric layer 114 that covers the third feature(s) 111 is polymerized. Additionally, a portion of the thin photodielectric layer 114 near the second feature(s) 110 is polymerized, and a remaining portion of the thin photodielectric layer 114 remains unpolymerized for cavity formation.

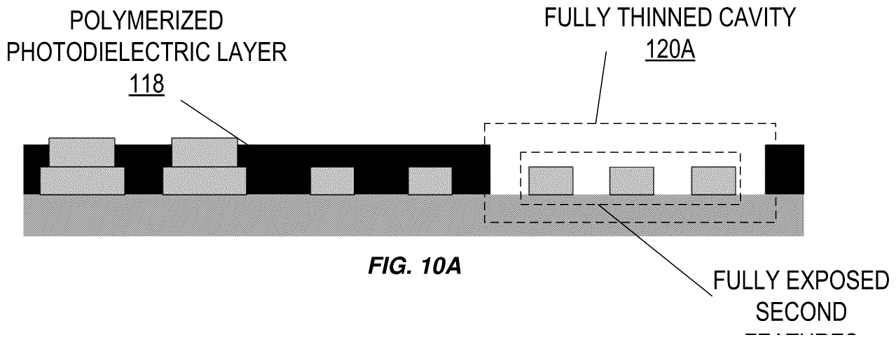

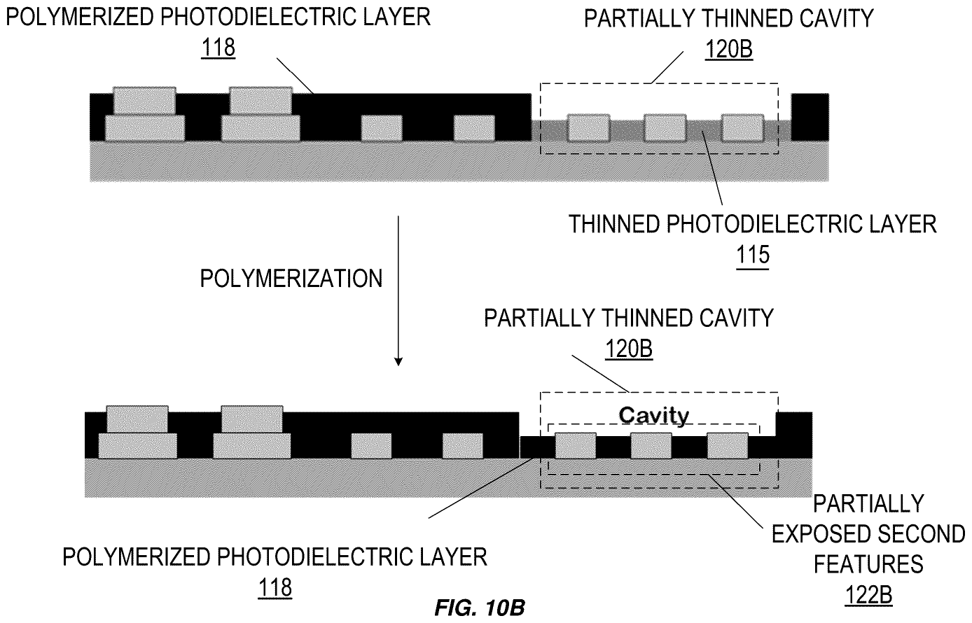

FIG. 10A is a diagram that illustrates the electronic substrate 100 after thinning of the remaining portion of the thin photodielectric layer 114 to form a fully thinned cavity 120A according to one embodiment of the present disclosure. Specifically, the remaining portion of the thin photodielectric layer 114 of FIG. 9 is thinned completely to form the completely thinned cavity 120A and to form fully exposed second features 122A (e.g., traces, etc.).

FIG. 10B is a diagram that illustrates the electronic substrate 100 after thinning of the remaining portion of the thin photodielectric layer 114 to form a partially thinned cavity 120B according to one embodiment of the present disclosure. Specifically, the remaining portion of the thin photodielectric layer 114 of FIG. 9 is thinned partially as a further thinned photodielectric layer 115 to form the partially thinned cavity 120B and to form partially exposed second features 122B (e.g., traces, etc.). The thinned photodielectric layer 115 is then unpolymerized to be a part of the polymerized photodielectric layer 118.

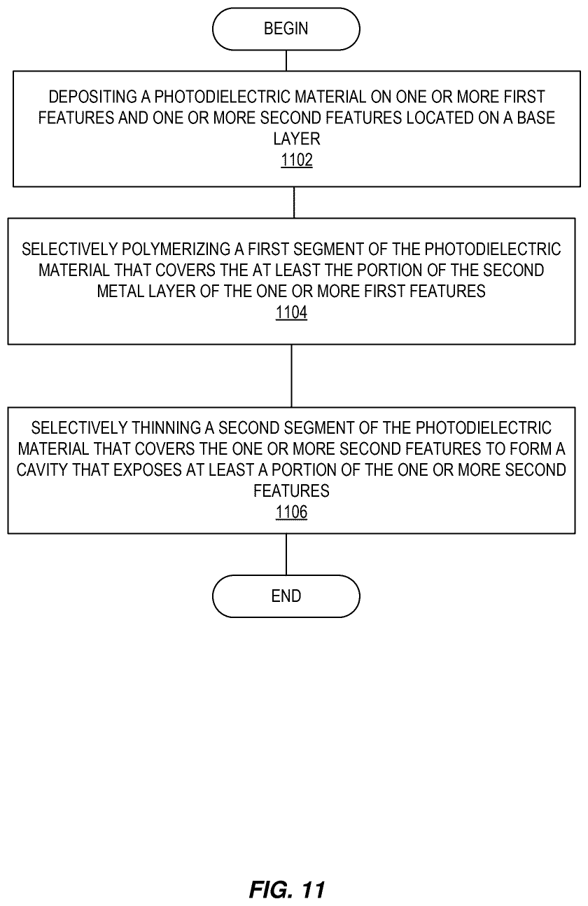

FIG. 11 is a flowchart for a method for fabricating an electronic substrate with a single dielectric layer for solder mask and cavity according to some embodiments of the present disclosure. At step 1102, a photodielectric material is deposited over one or more first features (e.g., first features 108 of FIGS. 6-10) and one or more second features (e.g., second features 110 of FIGS. 6-10) located on a base layer (e.g., base layer 102 of FIGS. 6-10). In some embodiments, an intermediate layer is located between the base layer and the features and photodielectric material.

The one or more first features are formed from a first metal layer and a second metal layer (e.g., layers 104 and 106 of FIGS. 6-10, etc.). A bottom surface of the first metal layer of the one or more first features contacts a top surface of the base layer, or contacts top surface of a layer in between the base layer and the first metal layer. A bottom surface of the second metal layer of the one or more first features contacts a top surface of the first metal layer or a top surface of a layer between the first metal layer and the second metal layer.

The one or more second features are formed from the first metal layer. A bottom surface of the first metal layer of the one or more second features contacts a top surface of the base layer. Alternatively, in some embodiments, the one or more second features are formed from the second metal layer.

The photodielectric material is deposited over the base layer, the one or more second features, and at least a portion of the second metal layer of the one or more first features to form a photodielectric layer (e.g., photodielectric layer 112 of FIG. 7, thin photodielectric layer 114 of FIG. 8, etc.). Specifically, in some embodiments, the photodielectric material is deposited such that a portion of the second metal layer of the one or more first features is exposed (e.g., exposed first features 116 of FIG. 8). Alternatively, in some embodiments, the photodielectric material is deposited such that the portion of the second metal layer of the one or more first features is fully covered by the photodielectric material such that a top surface of the second metal layer of the one or more first features contacts a bottom surface of the first segment of the photodielectric material (e.g., first features 108 of FIG. 7).

In some embodiments, one or more third features are also located on the base layer, and step 1102 further includes depositing the photodielectric material on the one or more third features located on the base layer. In some embodiments, the one or more third features are formed from the first metal layer, wherein the bottom surface of the first metal layer of the one or more third features contacts the top surface of the base layer or the top surface of a layer in between the base layer and the first metal layer, and the top surface of the first metal layer of the one or more third features contacts a bottom surface of a third segment of the photodielectric material.

At step 1104, a first segment of the photodielectric material is selectively polymerized to form a polymerized photodielectric layer (e.g., polymerized photodielectric layer 118 of FIG. 9). The first segment of the photodielectric material covers the at least the portion of the second metal layer of the one or more first features.

In some embodiments, prior to selectively polymerizing the first segment of the photodielectric material, the first segment of the photodielectric material is selectively thinned to expose a portion of the second metal layer of the one or more first features.

In some embodiments, at step 1104, the third segment of the photodielectric material is selectively polymerized. In some embodiments, the third segment of the photodielectric material is located between the first and second segments of the photodielectric material.

At step 1106, the second segment of the photodielectric material that covers the one or more second features is selectively thinned to form a cavity that exposes at least a portion of the one or more second features (e.g., cavities 120A/B of FIG. 10A/10B). In some embodiments, the second segment of the photodielectric material that covers the one or more second features is selectively thinned to form a cavity that exposes a portion of the one or more second features, and then the second segment of the photodielectric material is polymerized.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method for fabricating an electronic substrate, comprising:
providing a plurality of features on a base layer, wherein:
the plurality of features includes one or more first features and one or more second features; and
the one or more first features are formed from a first metal layer and a second metal layer, while the one or more second features are formed from the first metal layer, wherein the first metal layer is formed over a top surface of the base layer, and the second metal layer is formed over a top surface of the first metal layer without any via therebetween;
depositing a photodielectric material over the top surface of the base layer, wherein:
the photodielectric material partially encapsulates one or more first features, such that only a top portion of the second metal layer in each of the one or more first features is exposed through the photodielectric material, while the photodielectric material fully encapsulates one or more second features; and
no portion of the second metal layer in each of the one or more first features covers a top surface of the photodielectric material;
selectively polymerizing the photodielectric material, wherein at least a first segment of the photodielectric material that partially encapsulates the one or more first features is polymerized, while a second segment of the photodielectric material that fully encapsulates the one or more second features remains un polymerized; and
selectively thinning the second segment of the photodielectric material to form a cavity, wherein at least a top portion of the first metal layer in each of the one or more second features is exposed in the cavity, and the photodielectric material does not cover a top surface of each of the one or more second features.

2. The method of claim 1, wherein the first metal layer and the second metal layer in a same one of the one or more first features have a first width and a second width, respectively, wherein the first width is greater than the second width.

3. The method of claim 1, wherein a bottom surface of the first metal layer contacts the top surface of the base layer, and a bottom surface of the second metal layer contacts the top surface of the first metal layer.

4. The method of claim 1, wherein:
the second segment of the photodielectric material is selectively thinned to a thinned second segment of the photodielectric material, which partially encapsulates each of the one or more second features, such that the top portion of the first metal layer in each of the one or more second features is exposed in the cavity.

5. The method of claim 4 further comprises polymerizing the thinned second segment of the photodielectric material.

6. The method of claim 1, wherein the second segment of the photodielectric material is completely removed, such that each of the one or more second features is fully exposed in the cavity.

7. The method of claim 1, wherein depositing the photodielectric material over the top surface of the base layer comprises:
depositing the photodielectric material over the top surface of the base layer to fully encapsulate the one or more first features and the one or more second features; and
thinning the photodielectric material to expose the top portion of the second metal layer in each of the one or more first features, while maintaining full encapsulation of the one or more second features.

8. The method of claim 7, wherein thinning the photodielectric material is implemented by a grind process and/or an etch process.

9. The method of claim 1, wherein:
the plurality of features further includes one or more third features that are formed from the first metal layer; and
the one or more third features are fully encapsulated by the photodielectric material before selectively polymerizing the photodielectric material.

10. The method of claim 9, wherein a third segment of the photodielectric material that fully encapsulates the one or more third features is polymerized.

11. The method of claim 10, wherein the third segment of the photodielectric material is located between the first segment of the photodielectric material and the second segment of the photodielectric material.

12. The method of claim 1, wherein the base layer comprises a non-conductive layer.

13. The method of claim 1, wherein:
the one or more first features comprise one or more respective contact pads; and/or the one or more second features comprise one or more respective traces.

14. The method of claim 1, wherein the first metal layer and/or the second metal layer comprises copper.

15. The method of claim 1, wherein the photodielectric material is a film-type photodielectric or a liquid-type photodielectric.
